(19) United States
(12) Patent Application Publication
(10) Pub. No.: US 2022/0032264 A1
(43) Pub. Date: Feb. 3, 2022

(54) SOLID SUPPORT COMPRISING CARBON NANOTUBES, SYSTEMS AND METHODS TO PRODUCE IT AND TO ADSORBE ORGANIC SUBSTANCES ON IT

(71) Applicant: Danilo VUONO, Castrolibero (CS) (IT)

(72) Inventor: Danilo VUONO, Castrolibero (CS) (IT)

(21) Appl. No.: 17/299,260

(22) PCT Filed: Dec. 23, 2019
(86) PCT No.: PCT/IB2019/061278

§ 371 Date: Jun. 2, 2021

(30) Foreign Application Priority Data
Dec. 24, 2018 (IT) 102018000021040

(51) Int. Cl. B01J 20/20; B01J 20/10; B01J 20/28; B01J 20/32; B01J 20/34; C02F 1/28; B01D 15/20; C23C 16/26; C23C 16/44; C23C 16/46; C23C 16/54

(52) U.S. Cl. CPC B01J 20/205; C02F 2101/30; B01J 20/28004; B01J 20/28016; B01J 20/3214; B01J 20/3204; B01J 20/3293; B01J 20/324; B01J 20/3475; B01J 20/3416; C02F 1/288; C02F 1/283; B01D 15/203; C23C 16/26; C23C 16/4417; C23C 16/46; C23C 16/54; B01J 20/103

(57) ABSTRACT

Method for manufacturing an inert solid support with optionally functionalised carbon nanotubes (CNTs), comprising the steps of: i) providing an inert solid support and at least one catalytic metal associated with, or absorbed in, or adsorbed/deposited on, said support, said metal being optionally selected from among the group consisting of iron, cobalt, nickel, molybdenum and combinations thereof; ii) supplying a source of gaseous, liquid or solid carbon to the catalytic metal; iii) through chemical vapor deposition (CVD), depositing at least part of the carbon source at the catalytic metal as CNTs, stably connected to the inert solid support. The present invention further regards an inert solid support and a separation method.

The present invention regards a method for manufacturing an inert solid support with carbon nanotubes (CNTs), a solid support with CNTs, an adsorption system, a separation method, and a device for manufacturing an inert solid support with carbon nanotubes (CNTs).

### BACKGROUND OF THE INVENTION

Carbon nanotubes were discovered by Iijima in 1991 [1]. He analysed the samples produced by arc discharge in He atmosphere. With TEM microscopy he observed some very interesting hollow tubule-like structures, but no further investigation was made because the research group was pursuing other objectives.

The first publication on these nano-sized hollow tubes was produced by some Russian researchers in the mid-50s and later by Endo and his collaborators [2,3].

Carbon nanotubes (CNTs) consist of a graphene sheet rolled-up to form a tube, the latter structures being referred to as single-walled carbon nanotubes (SWCNTs). On the other hand, when two or more concentric tubes are formed to form thicker structures, multi-walled carbon nanotubes (MWCNTs) are obtained.

Initially, arc discharge was the most widely used method for producing CNTs. This method was already known and widely used for the production of carbon filaments and fibres.

Later on, other production synthesis techniques such as laser ablation or chemical vapour deposition (CVD) were considered in the production thereof.

The previous methods are therefore the three main methods of synthesis of these nanomaterials.

Some efforts were made to look for other possibilities of growing nanotubes, but without success: this is certainly due to the high costs of the apparatuses that have been used over the years, the price of the materials used as catalyst, the particular synthesis conditions, such as high pressures and temperature, or the use of exceptional manufacturing conditions.

Therefore, there was a return to the mere optimisation of the old methodologies, adapted to new conditions, rather than discovering new technologies.

Nowadays, arc discharge and chemical vapor deposition are widely applied for the formation of carbon nanotubes. Many studies have been made to improve the quality and quantity of production of these nanomaterials by optimising synthesis process thereof.

As a result, some changes in the CVD method—such as the use of plasma, microwaves or radio frequencies connected to the CVD—were discovered.

### Technical Problem

In recent years there has been a growing interest in these nanostructured materials, not only in the industry of composite materials (where CNTs are widely applied), but also in the environmental industry.

Thanks to the excellent adsorbing properties, nanotubes have overwhelmingly entered the field of civil and industrial water filtration.

Numerous researches have developed technologies based on the chemical/physical properties of nanotubes and have used them to improve already widely optimised processes [4].

One of the limitations in the use of CNTs is of a dimensional nature. More precisely, nanometric measurements of nanotubes do not facilitate their use in industrial filtration plants, such as in plants where activated carbons are currently used.

Various technical solutions which have the common ground of aiming at preventing the drawbacks linked to the undesired nanotube entrainment phenomena have been developed in recent years.

However, the solutions theorised to date entail implementation costs which—up to date—significantly outweigh the benefits that can be obtained.

### BIBLIOGRAPHIC REFERENCES

[1] lijima, S. Helicalmicrotubules of graphitic carbon. Nature 1991, 354, 56-58.
[2] Radushkevich L. V.; Lukyanovich V. M. O struktureugleroda, obrazujucegosjapritermiceskomrazlozeniiokisiuglerodanazeleznomkontakte. Zurn. Fisic. Chim. 1952, 26, 88-95.
[3] Oberlin, A.; Endo, M.; Koyama, T. Filamentous growth of carbon through benzene decomposition. J. Cryst. Growth 1976, 32, 335-349.
[4] E. Fontananova, M. A. Bahattab, S. A. Aljlil, M. Alowairdy, G. Rinaldi, D. Vuono, J. B. Nagy, E. Drioli and G. Di Profio, From hydrophobic to hydrophilic polyvinylidenefluoride (PVDF) membranes by gaining new insight into material's properties, RSC Adv., 2015, 5, 56219-56231.

### SUMMARY OF THE INVENTION

Thus, the present invention falls within the context outlined above, aiming at providing a low-cost method capable of providing an inert solid support to which a plurality of CNTs is connected or fixed, so that carbon nanotubes—aggregated in clusters larger than the nanometric scale—are less subjected to the entrainment phenomenon.

More precisely, the inert solid supports comprising (or functionalised with) the carbon nanotubes constitute adsorbing units capable of being used with greater versatility with respect to conventional nanotubes.

A further object of the invention is a process for separating organic substances by means of the inert solid support described herein. The idea is based on the use of a support with high performance CNTs as an adsorbent means with respect to organic substances.

### BRIEF DESCRIPTION OF THE DRAWINGS

FIG. 1: Reactive Black-5 removal kinetics using 1.36 g of silica sand (0.03 g of carbonaceous product on the sand surface);

FIG. 2: Kinetic adsorption curves for three different textile dyes with starting concentration equal to 100 mg/l, using 2.73 g of adsorbent material (containing 0.06 g of carbonaceous product on the silica surface);

FIG. 3: Breakthrough curve of a continuous test on water polluted by reactive Black-5 at 37 mg/l. Total weight of the adsorbent material 113.63 g; Delivery flow rate in column 5 ml/min;

FIG. 4: Concentration profiles with respect to the normalised heights of the adsorbent material in a column measuring 25 cm length-wise and 2 cm internal diameter-wise;

FIG. 5: Breakthrough curve of a continuous test on water polluted by reactive Black-5 at 7.5 mg/l. Total weight of the adsorbent material 90 g; Delivery flow rate in column 10 ml/min;

FIG. 6: Concentration profiles of a reactive Red 159 removal column by means of different bed heights formed by the adsorbent material and at different tapping times;

FIG. 7: Plant diagram used for the removal of industrial reactive Yellow 81 in water;

FIG. 8: Trend as a function of the concentration time of current A;

FIG. 9: Trend as a function of the concentration time of current B;

FIG. 10: SEM photo of an inert solid support without CNTs;

FIG. 11: SEM photo of an inert solid support with the catalytic metal (white spots) distributed on the surface;

FIG. 12: SEM photo of an inert solid support with CNTs;

FIG. 13: SEM photo of an inert solid support with CNTs, where the support is shown as a cross-section;

FIG. 14: Adsorption system, for example a filter, of at least one organic substance according to a possible embodiment of the present invention;

FIG. 15: Orthogonal cross-section along the plane XV-XV indicated in FIG. 14;

FIG. 16: Adsorption system according to another possible embodiment of the present invention;

FIG. 17: Schematisation of an apparatus for manufacturing an inert solid support with carbon nanotubes, according to a possible embodiment (apparatus of the “batch” type);

FIG. 18: Schematisation of an apparatus for manufacturing an inert solid support with carbon nanotubes, according to another possible embodiment (apparatus of the continuous type);

FIG. 19: temperature profile inside the manufacturing device of FIG. 18 as a function of a radial direction with respect to the rotation axis R.

### DETAILED DESCRIPTION OF THE INVENTION

The objectives outlined above are achieved through a method for manufacturing an inert solid support with optionally functionalised carbon nanotubes (also referred to as “CNTs” for the sake of brevity in the following description), comprising the steps of:

i) providing an inert solid support and at least one catalytic metal associated with, or absorbed in, or adsorbed/deposited on such support;
ii) supplying at least one source of gaseous, liquid or solid carbon to the catalytic metal;
iii) through chemical vapor deposition (CVD), depositing at the catalytic metal at least part of the carbon source as CNTs, connected (for example: stably) to the inert solid support;

Hence, the manufacturing method outlined above innovatively allows to achieve not only a synthetic approach for carbon nanotubes, but also an anchorage thereof to the inert solid support.

For the sake of brevity, in the following description the product of step iii)—that is, the inert solid support comprising the CNTs—is also referred to as “adsorbent material”.

According to an embodiment, the inert solid support is in the form of particulate, granule or pellet.

Preferably, the inert solid support is not in the form of mineral discs of nanometric thickness.

According to an embodiment, the inert solid support is porous or non-porous.

According to an embodiment, the inert solid support comprises or consists of a refractory material.

More precisely, it is preferable that the solid support be inert and refractory at least in the temperature range at which step iii) occurs.

According to different embodiments, the inert solid support is selected from among the group comprising aluminium silicate (for example: mullite), silico-aluminates, quartz sand, quartz, alumina or aluminium oxide (for example: corundum), silicon carbide, silicon nitride, zirconium oxide, calcium-magnesium carbonate (for example: dolomite), clay refractory materials, zeolite (for example natural or synthetic) and combinations thereof. Preferably, the inert solid support comprises or, alternatively, consists of quartz sand.

According to another embodiment, the particulate, granule or pellet has an over-nanometric particle size distribution.

It should be observed that, in this description, the expression “over-nanometric” is used to indicate sizes greater than those of free carbon nanotubes, for example greater than the diameters characterising a nanotube, usually comprised in the range from 0.7 to 10 nm. For example, this expression will be used to indicate a particle size distribution of the order of at least one micrometric unit, or greater than a micrometre or possibly at least equal to a millimetre. Preferably, the inert solid supports have an average size distribution comprised from 0.1 mm to 5 mm, preferably comprised from 0.2 mm to 2 mm, even more preferably comprised from 0.3 mm to 1 mm.

According to various embodiments, the catalytic metal is selected from among the group consisting of iron, cobalt, nickel, molybdenum and combinations thereof.

For example, only one catalytic metal could be used. Or at least two or at least three catalytic metals could be used.

According to other embodiments, one or more other transition metals could be used as the catalytic metal in the present invention.

According to an advantageous variant, the catalytic metal or the plurality thereof is in ionic form.

With regard to step ii), the carbon source is advantageously gaseous.

Nevertheless, the carbon source, or a carbon source precursor, could be in liquid or solid phase, and it could be vaporised, sublimated or brought to aerosol form prior to the supply step ii).

According to another embodiment, more than one source, for example two different types of gas, or a gas and a vaporised liquid precursor could be used in step ii).

According to an embodiment, the carbon source could be selected from among a gaseous, saturated or unsaturated organic compound, advantageously unsubstituted by heteroatoms (that is to say free of atoms other than carbon and hydrogen).

According to possible variants, the carbon source could comprise or consist of ethylene, acetylene, methane, or ethane.

According to possible variants, the carbon source could comprise or consist of heavy liquids such as xylene or benzene and/or polymeric solids comprising carbon, such as polyacrylonitrile or polypyrrole, preferably pyrolyzed.

According to a variant, step iii) is carried out at a temperature comprised in the range from 500−850° C., for example comprised in the range from 650−750° C.

As concerns variants using methane as a carbon source, the temperature of the aforementioned ranges could be increased to about 900° C.

According to a further variant, step iii) is carried out in an inert atmosphere, for example in a nitrogen and/or argon atmosphere.

According to an embodiment, the CNTs could be at least partially functionalised with —OH and —CO₂H groups, for example at structural defects of the nanotube.

For the sake of completeness, indicated are some operating parameters of the present method, which can be implemented independently with respect to each other:
optional pre-conditioning time of the inert solid support of step i) at room temperature: 5-20 minutes;
flow rate of the carbon source (for example C₂Ha) in step ii): 200-1200 ml/min;
duration of step iii): 5-20 minutes (variable depending on the selected temperature);
optional nitrogen flow rate in step iii): 100-600 ml/min;
optional argon flow rate in step iii): 10-30 ml/min.

The objectives outlined above are also achieved by means of an inert solid support comprising optionally functionalised CNTs deposited on and connected to said support, in a preferably stable manner, wherein the support comprises at least one catalytic metal associated with, or absorbed in, or adsorbed/deposited on, such support.

Given that such support is advantageously obtained through the method according to any one of the preceding embodiments, even were this not to be explicit, this support may comprise any preferred or supplementary characteristic among those described.

Preferably, the inert solid support is in the form of particulate, granule or pellet with an over-nanometric particle size distribution.

According to an embodiment, the CNTs are in the form of scattered bundles or tangle, grouped at the catalytic metal.

The objectives outlined above are also achieved by means of an adsorption system 10 of at least one organic substance (for example of at least one organic pollutant) comprising the inert solid support described above, wherein the carbon nanotubes are configured to adsorb the organic substance (for example selectively).

Referring for example to the embodiment of FIG. 14, said adsorption system 10 comprises a casing 1, a first supply duct 6 and a first outlet duct 8.

The casing 1 delimits an inner compartment 2 in which an adsorption bed 4 consisting of a plurality of said inert solid supports comprising CNTs is arranged. Said inert solid supports are preferably arranged randomly in the casing 1, and form a plurality of tortuous passages for a liquid to be purified in the adsorption bed 4.

Preferably, the inert solid supports of the adsorption bed 4 have an average size distribution comprised from 0.1 mm to 5 mm, preferably comprised from 0.2 mm to 2 mm, even more preferably comprised from 0.3 mm to 1 mm.

The first supply duct 6 is configured to supply the liquid to be purified to the adsorption bed 4, wherein said liquid to be purified comprises said at least one organic substance, for example dissolved, dispersed or suspended in the liquid.

In this connection, the first supply duct 6 is functionally connected to at least one supply pump 24, configured to displace said liquid in the first supply duct 6, for example by drawing it from a vat or basin 30.

Preferably, the adsorption system 10 comprises dispensing means 12 of the liquid to be purified on the adsorption bed 4, positioned at one end of the first supply duct 6. More preferably, the dispensing means 12 (for example a plurality of nozzles) are arranged vertically above the adsorption bed 4, so that the liquid to be purified flowing out from the dispensing means 12 falls onto said bed 4 due to the force of gravity.

The first outlet duct 8, is configured for conveying an at least partly purified liquid from said at least one organic substance outside the inner compartment 2. Therefore, the liquid percolated through said adsorption bed 4 is conveyed outside the casing 1 through the first outlet duct 8.

Preferably, the adsorption system 10 comprises collecting means 14 of the at least partly purified liquid, arranged inside or below the adsorption bed 4 and fluidically connected to the first outlet duct 8.

The collection means 14 preferably comprise one or more radial collectors 26, configured to convey the purified liquid toward the first outlet duct 8. Preferably, the first outlet duct 8 is arranged approximately centrally with respect to the casing 1, and said one or more radial collectors 26 are arranged radially with respect to said first outlet duct 8.

The sizing of the casing 1 depends on the technological requirements of the adsorption system, the type of organic substance to be adsorbed, and the amount and/or contact surface of the inert solid supports comprising CNTs.

By way of example, the casing 1 could be hollow-cylindrical-shaped, with a cylinder diameter comprised from 0.1 m to 2 m, preferably from 0.4 m to 1 m, and with a cylinder height comprised from 0.5 m to 3 m, preferably from 0.75 m to 2 m.

By way of further example, the casing 1 could have an internal capacity such to contain from 10 kg to 500 kg of adsorbent material, preferably from 15 kg to 300 kg, more preferably from 20 kg to 250 kg.

According to an embodiment, for example shown schematically in FIG. 16, two casings 1 arranged in parallel to each other could be used. Preferably, said casings could be sized in a mutually different manner. By way of example, a first casing could have dimensions (for example diameter and/or height) comprised between 1.05 and 5 times the dimensions of a second casing, preferably comprised from 1.1 to 3 times, even more preferably comprised from 1.15 to 2 times.

Preferably, the adsorption system 1 comprises a second duct 16 for supplying a polar and aprotic solvent (regeneration solvent), for example acetone or dimethyl sulfoxide (DMSO), to the adsorption bed 4, a second outlet duct 18 for conveying said regeneration solvent comprising said at least one organic substance—desorbed by the CNTs of said inert solid supports—outside the inner compartment 2, heating means 20 and a venting opening 22.

Thus, this embodiment provides for that the inert solid supports comprising CNTs can be regenerated, by desorption of the organic substance.

The heating means 20 are in a thermal contact with, preferably housed within, the adsorption bed 4 so as to evaporate residues of the regeneration solvent from said bed 4, and the venting opening 22 of the evaporated regeneration solvent flows through said casing 1.

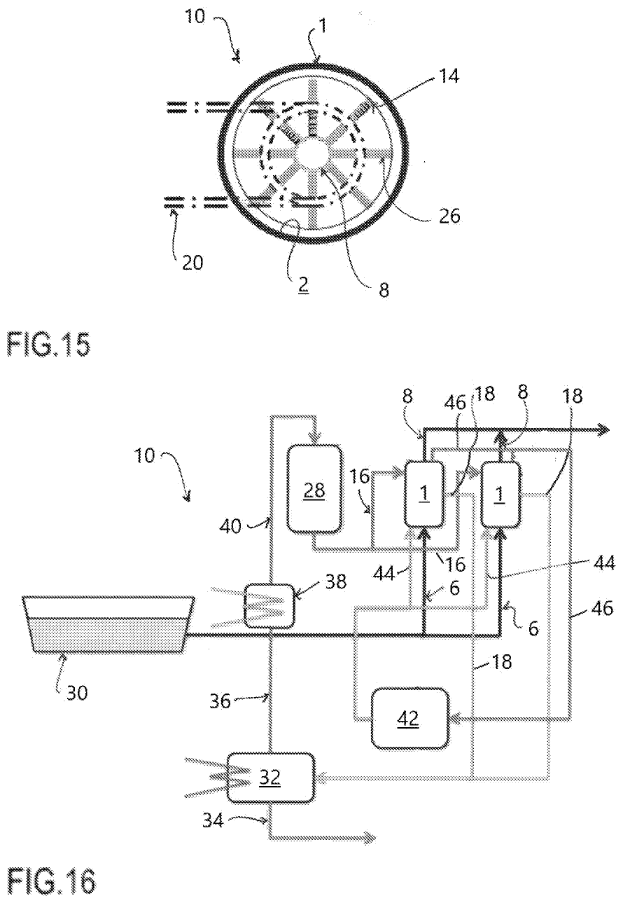

Preferably, the heating means 20 comprise a coil at least partly housed in the adsorption bed 4. Even more preferably, said coil is wound in spirals in the adsorption bed 4, as shown for example in FIG. 15.

Preferably, the heating means 20 is controllable (for example through management and control means not shown) to reach an evaporation temperature of the regeneration solvent, more preferably comprised from 40° C. to 70° C. (for example comprised from 50° C. to 55° C. should the regeneration solvent be acetone).

The adsorption bed 4 preferably has a vacuum factor irrespective of the amount of organic substances adsorbed on said CNTs. More preferably, the vacuum factor is comprised from 35% to 60%, preferably comprised from 40% to 55%, even more preferably comprised from 40.5% to 48%, for “average” packings (i.e. in the presence of inert solid supports with an average size distribution comprised from 0.2 mm to 2 mm, for example about 1 mm) of said inert solid supports.

In this description, the expression “vacuum factor” is used to indicate—for a given total volume occupied by inert solid supports comprising CNTs—a percentage ratio between a vacant internal volume between said inert solid supports (interstitial or interparticle volume) and said occupied total volume.

According to various embodiments, the adsorption system is at least part of a filter, a sieve, a membrane, a filling or adsorption body, an adsorption column, or the like.

With reference to FIG. 16, the adsorption system 10 could comprise two of said casings 1, arranged in parallel, supplied by first supply ducts 6. Preferably, the first supply ducts 6 could be fluidically connected to a basin or vat 30 of liquid to be purified. Each casing 1 is connected to a respective first duct 8 for the outflow of the liquid, at least partly purified.

In the system shown in FIG. 16, number 28 is used to indicate a regeneration solvent tank which is connected to the two casings 1 by means of a pair of second supply ducts 16. Second outlet ducts 18 connect the casings 1 with a unit 32 for the evaporation of the regeneration solvent, inside which the desorbed organic substance is separated from the regeneration solvent. The desorbed organic substance is removed by means of a discharge duct 34, while the regeneration solvent is made to flow through a first intermediate duct 36, a condensation unit 38 and a second intermediate duct 40 so as to supply the regeneration solvent tank 28 again, once the regeneration solvent has been re-condensed in liquid form.

Preferably, in the embodiment of FIG. 16 there could also be a water tank 42, connected at the outlet with the casings 1 through third intermediate ducts 44, to eliminate traces of the regeneration solvent. The casings 1 are connected at the outlet with the water tank 42, so as to form a circuit, by means of fourth intermediate ducts 46.

The present invention also regards a separation method comprising the following steps.

According to one embodiment, the separation method comprises or consists of a purification method.

According to a variant, such method is continuous, semi-continuous or discontinuous.

According to a further variant, the method is a closed-circuit method.

The method comprises the steps of:

a) providing an inert solid support according to the preceding variants;
b) contacting the inert solid support with a liquid containing at least one organic substance to be separated, for example containing at least one organic pollutant;
c) adsorbing the organic substance on the carbon nanotubes of the inert solid support, so as to separate it from the liquid.

Optionally, such method comprises the steps of:

d) desorbing the organic substance of step c) from the carbon nanotubes, optionally collecting the desorbed organic substance;
e) re-using at least part of the inert solid support of step d) in step a).

According to an embodiment, step d) comprises at least one sub-step of washing the carbon nanotubes with a polar and optionally aprotic solvent, for example acetone or dimethyl sulfoxide (DMSO).

According to a further embodiment, step d) comprises a sub-step of evaporating the polar solvent so as to leave a residue of desorbed organic substance.

For example, the sub-step of evaporating could be carried out at low pressure (reduced pressure).

According to a variant, the residue could be a dry residue.

According to another variant, the residue could be a liquid phase residue.

Lastly, the present invention regards a device 50 for manufacturing an inert solid support with carbon nanotubes (CNTs), designed to implement said manufacturing method.

Said manufacturing device 50 comprises a tubular furnace 48 and a reactor 58, rotating with respect to said furnace 48 around a rotation axis R.

Said manufacturing device 50 comprises a loading zone 52, a heating zone 54 at the tubular furnace 48, and a discharge zone 56. The reactor 58 is rotatably mounted with respect to said furnace 48 so that a plurality of segments of said reactor 58 is movable in a circular motion from the loading zone 52, to the heating zone 54, to the discharge zone 56.

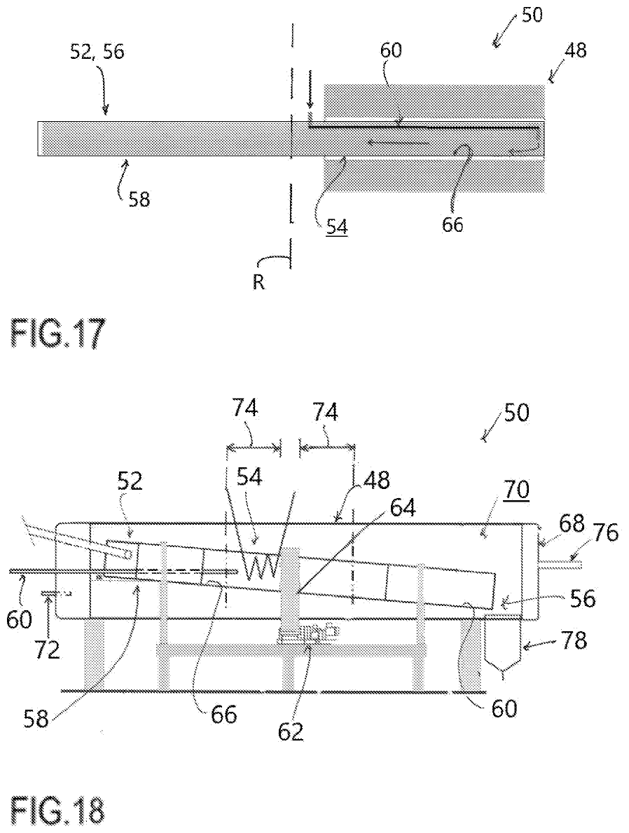

In the embodiment shown in FIG. 17, the loading zone 52 and the discharge zone 56 are at least partially overlapped, for example being coincident.

Preferably, a collector or a discharge hopper 78 could be provided at the discharge zone 56 to move the inert solid supports comprising the CNTs away from the rotary reactor 58.

In the embodiment shown in FIG. 18, the loading zone 52 and the heating zone 54 are preferably offset in a radial direction with respect to the rotation axis R. More preferably, the loading zone 52 and the discharge zone 56 are arranged diametrically opposite with respect to said axis R. Preferably, the heating zone 54 substantially corresponds to a reaction zone (in which the chemical vapor deposition, CVD, occurs), in which the CNTs are deposited on, and stably connected to, the inert solid supports. Preferably, the reaction zone is an annular volume 74 which extends around the rotation axis R, and which is preferably radially delimited towards the outside by the loading zone 52 and/or by the discharge zone 56.

The rotary reactor 58 is preferably made of quartz glass. By way of example, the rotary reactor 58 could have a diameter comprised from 1 m to 4 m, preferably comprised from 1.5 m to 3 m.

Preferably, the rotary reactor 58 is driven through of motor means 62, for example only schematically shown in FIG. 18, more precisely through means for the transmission of motion from said motor means 62 to said rotary reactor 58.

In particular, the transmission means could comprise a gear or a gear wheel driven by the motor means 62, and a rotating shaft 64 rotatably integrally joined with the rotary reactor.

The rotation axis R is preferably substantially vertical.

In the embodiment of FIG. 17, the rotary reactor 58 delimits a support surface 66 substantially orthogonal to the rotation axis R.

In the embodiment of FIG. 18, the rotary reactor 58 delimits a support surface 66 non-orthogonal with respect to the rotation axis R, for example inclined at an angle comprised from 2° to 20°, preferably comprised from 5° to 15°, even more preferably comprised from 8° to 12° (for example about 10°) with respect to a plane orthogonal to said axis R. This inclination is specially designed to promote a movement of the inert solid supports from the loading zone to the heating zone, to the discharge zone due to the combined motion of the rotary reactor 58 (rotary) and the displacement of the inert solid supports (translational) along the support surface 66.

In the heating zone 54 there occurs the chemical vapor deposition of the CNTs, in an inert atmosphere and in the presence of the carbon source, preferably gaseous, supplied to the heating zone 54 by means of a pipe 60 for supplying said source.

In the embodiment of FIG. 18, the manufacturing device 50 comprises an outer skirt 68. Preferably, the outer skirt 68 is also present in the embodiment of FIG. 17, although not illustrated. More preferably, the outer skirt 68 is at least partially (for example: completely) made of quartz glass.

The outer skirt 68 delimits a skirt compartment 70 in which the rotary reactor 58 is at least partly arranged (for example: completely), and in which a controlled atmosphere of inert gas is maintained. In this connection, an inert gas inlet 72 which flows through the outer skirt 68 is preferably provided. A gas outlet 76 is preferably also provided so that a synthesis gas (containing an unreacted carbon source and inert gas) can be moved away from the rotary reactor 58.

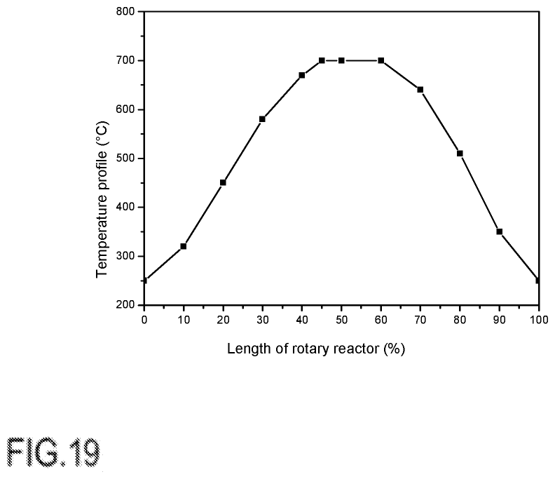

Preferably, the temperature profile in the manufacturing device 50 of FIG. 18 as a function of a radial direction (percentage) with respect to the rotation axis R is shown in FIG. 19. Such diagram shows that the temperatures are lower in the loading zone 52 and in the discharge zone 56, while there is a maximum temperature value, approximately 700° C., in the heating zone 54.

It is interesting to note that, by means of a profile thus designed, the inert solid supports without CNTs undergo a pre-heating before reaching the heating zone 54—which corresponds to the reaction zone—and that the inert solid supports comprising the CNTs subsequently undergo a gradual cooling (not sudden) as they are displaced toward the discharge zone 56.

### Fields of Application of the Invention

The inert solid support comprising CNTs provides a performing method whose flexibility and simplicity of implementation offers application possibilities in the most varying problems in the field of separation or purification of water polluted by organic substances.

In fact, the invention can be used in the purification or regeneration of water faults, polluted water basins, storage tanks, waste or industrial liquids (for example containing pigments).

Hereinafter, the present invention will be illustrated based on some examples, solely provided by way of non-limiting example.

### EXAMPLES

### Example 1: Preparing Synthesis Catalysts

Predefined amounts of at least one salt selected from among the group consisting of cobalt acetate, nickel acetate, iron nitrate, cobalt nitrate, iron acetate, nickel nitrate, iron chloride, or combinations thereof are mixed in suitable amounts of distilled water, and the solution thus obtained is stirred mechanically for about 30 minutes.

By way of example, the solutions could contain about 100-400 g of each salt for about 200-2000 ml of water.

However, it should be considered that in case of excessive dilutions of the salt or salts in solution (for example: should the water volume exceed 1200 ml for about 550 g of total salt), a small presence of activated metal sites on the support is expected, and therefore a relatively low efficiency of the catalytic metal.

Taking for example the mullite inert solid support, the following amounts of water and salt/s could be used to obtain the aforementioned solution:
200 ml of water for a mixture of salts consisting of 115 grams of nickel acetate tetrahydrate and 212 grams of cobalt acetate tetrahydrate; or
600 ml of water for a mixture of salts consisting of 312 grams of cobalt nitrate hexahydrate and 362 grams of iron nitrate nonahydrate.

An inert solid support amount is contacted with the solution obtained in the previous manner, according to a millilitre ratio of solution for each gram of inert solid support equal to 2, and it is mixed so that the solid has a uniform colour. Subsequently, drying is carried out at 80° C. for 24 hours.

The supported catalytic metal thus prepared is ready to be used in step iii) of deposition by means of CVD.

### Example 2: Depositing Carbon Nanotubes on the Solid Support by Means of CVD

80 grams of a supported catalytic metal obtained according to Example 1 are introduced into a quartz flask, which is in turn introduced into a quartz reactor.

They are conveyed to the hermetically sealed reactor, under inert atmosphere, using 1000 ml/min of nitrogen together with 200 ml/min of argon for 5 mins.

The temperature is then raised with a ramp of 10° C./min up to 700° C., after which there follows a 10 min wait with the reactor closed and under inert environment.

Lastly, 400 ml/min of ethylene (C₂H₄) are conveyed to the reactor for 20 mins, after which the reactor is cooled and—after waiting another 10 mins—the flow of the carrier gas is stopped.

The solid support with CNTs is then collected from the reactor.

### Example 3: Application on Industrial Textile Dyes

An adsorbent material consisting of CNTs on silica sand of measuring between 400 and 800 μm and with an average content of carbon nanotubes equal to 2.2% by weight was used for this application.

Batch tests on various dyes were conducted by treating 20 ml of water with dyes at different concentrations, with 0.03 or 0.06 g of carbonaceous product, corresponding to 1.36 g or 2.73 g of silica sand, respectively. Tapping was carried out at different treatment times, to test the variation of the concentration of the dye over time and to produce kinetic trends with respect to the adsorbing capacity of the material.

### Experimental Materials and Methods Used to Determine the Amount of Dyes in Samples of Polluted Water.

The assessment of concentrations of water polluted by industrial textile dyes is conducted by means of quantitative UV-VIS analysis. Each UV-VIS analysis related to batch removal of the dye at different treatment times contributed to the kinetic development of the adsorption phenomenon.

### Kinetic Batch Study

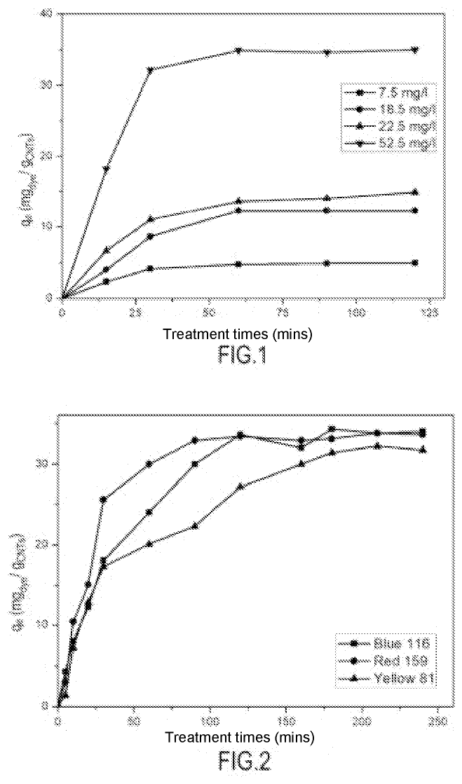

The kinetic curves relating to the removal of reactive Black-5 dye at concentrations between 7.5 mg/l and 22.5 mg/l are shown in FIG. 1.

The adsorbing capacities of the adsorbent material increase as a function of the concentration, but they do not reach its saturation if not with a concentration of 52.5 mg/l. The curves stabilise at around 30 mins, the maximum adsorption capacity solely with respect to the amount of carbonaceous product is 35 mg_{Dye}/g_{CNTs}.

FIG. 12 instead shows the kinetic behaviour of other three dyes (Blue 116, Red 159 and Yellow 81) used in a study for the purification of polluted water by means of carbon nanotubes in powder form autogenerated by means of the CCVD method.

The compositions of the three dyes are at 100 mg/l, while 2.73 g of adsorbent material (containing 0.06 g of carbonaceous product) was added to the solution.

The three kinetic curves are between 34 and 31-32 mg_{Dye}/g_{CNTs}, values very close to those of the adsorption capacities of the powder nanotubes, but the stabilisation times for the three curves are slightly higher than in the previous study.

Reactive Red 159 shows to have the fastest kinetic removal, while reactive Yellow 81, although still reaching high adsorption capacities (about 32 mg_{Dye}/g_{CNTs}) stabilises at considerably higher times with respect to the other two Dyes.

The trends confirm the superior performance of these materials with respect to Activated Carbons, already tested as reference materials in previous studies. The characterisation leads to considering the use of long contact times, and therefore low delivery rates, in order to optimise a possible continuous application.

### Example 4: Test of Continuous Adsorption of Water Polluted by Reactive Black-5 Dye

A filter measuring about 2 cm diameter-wise and 25 cm length-wise was prepared. A peristaltic pump was connected thereto to allow the water sample polluted by the reactive Black-5 dye to be conveyed from the starting container to the filter and then to the final storage container. Filtered samples (in addition to a polluted water sample to set the initial treatment conditions) were subjected to UV-VIS analysis so as to determine the final concentration at different times.

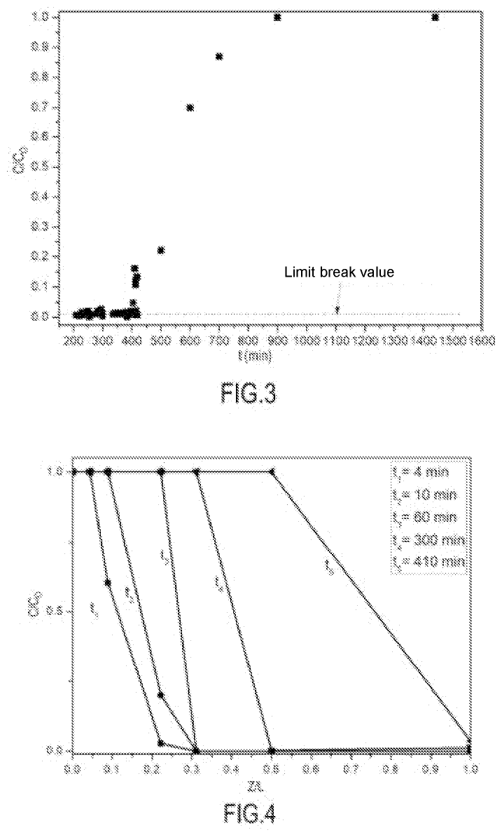

FIG. 3 shows a breakthrough curve constructed using 113.63 g of adsorbent material (weight of the carbonaceous product equal to 2.5 g).

The readings of the output data (obtained from the UV-VIS analyses), although revealing some instabilities in the initial part, never exceed the C/Co ratio equal to 0.05, considered as break value and corresponding to an output composition of 3.9-4 mg/l. Starting from this composition, the dye starts to be clearly visible and the column is unable to remove the pollutant with the same efficiency. The corresponding breakthrough time is about 350 mins.

FIG. 4, on the other hand, shows the concentration profiles in the column at different heights and normalised with respect to the total length of the column, of 25 cm. The integration of the upper part of this curve allows to obtain the adsorption capacity of the material, still with respect to the weight of the carbonaceous product only distributed on the silica sand surface higher than 34 mg_{Dye}/g_{CNTs}, identified in the previous batch assessments.

At 410 min (slightly over 6 h) the column begins to no longer remove the totality of the dye which, although in traces, begins to “pass”. For times over 410 minutes, the column can be considered exhausted and ready for possible regeneration.

### Example 5: Test of Continuous Adsorption of Water Polluted by Reactive Red 159 Dye

The continuous removal of Reactive Red 159 in a column measuring 4 cm diameter-wise and with a total length of about 20 cm was tested. 90 g of adsorbent material (on whose surface about 2 g of carbonaceous product are distributed) were used for the test.

FIG. 5 shows the breakthrough curve regarding these tests. The delivery flow rate of water contaminated with Reactive Red 159 is 10 ml/min. In this case, the break value, still defined at 0.05 of C/Co, and corresponding to the output concentration equal to 0.37 mg/l, a value at which the dye can be seen in the output current from the adsorption column.

The corresponding breakthrough time is about 150 mins, while the adsorption capacity calculated from the continuous data is equal to 22.5 mg_{Dye}/g_{CNTs}.

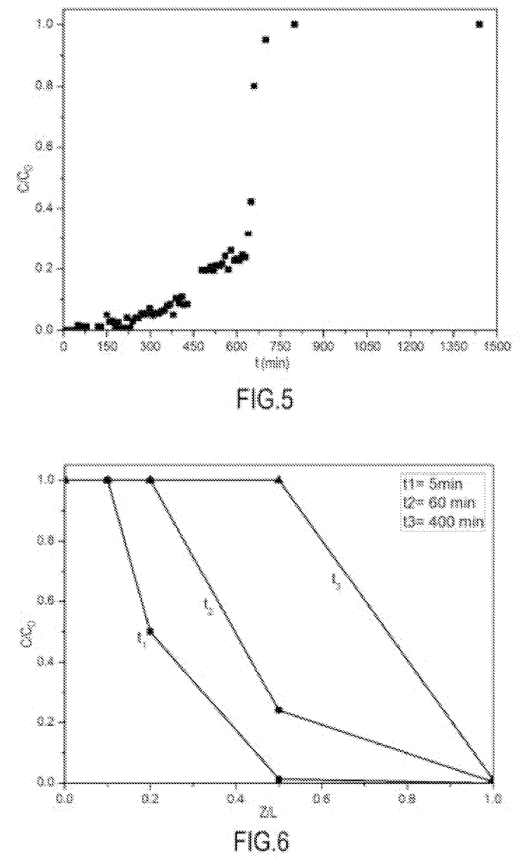

FIG. 6 instead shows the concentration profiles obtained as a function of three height values of the column normalised with respect to their highest value (10 cm).

### Example 6: Adsorption Test in a Reactive Yellow 81-Polluted Water Closed-Circuit Adsorption Column

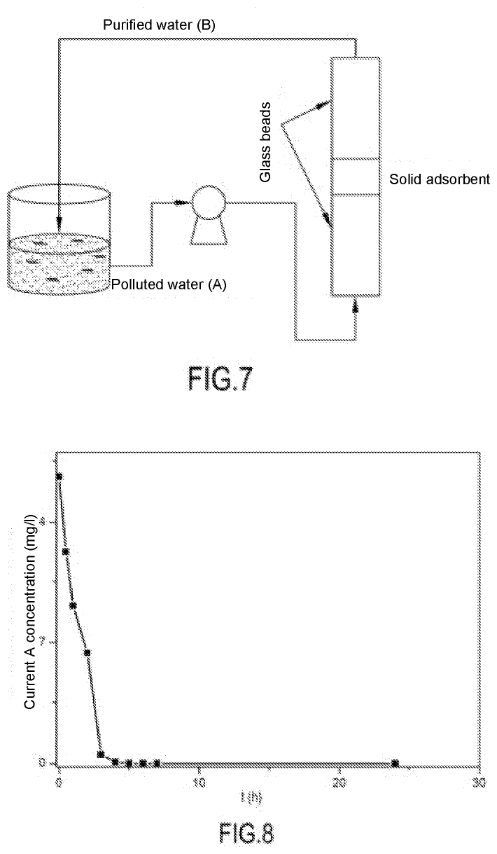

The test was conducted using Reactive Yellow 81 and the adsorbent material consisting of alumina pellets (215 g) on whose surface the carbonaceous product (3.87 g) was distributed. The test used a continuous configuration, shown in the diagram of FIG. 7.

The delivery rate was set at about 32 ml/min. The composition of the dye dispersed in a tray containing 61 of solution is equal to 16.6 mg/l. The previous characterisation suggests that the column will not be exhausted at the end of the test, even when operating with flow rates which should limit the contact times in the column between the water to be purified and the adsorbent material.

FIG. 8 shows the trend of the pull-out concentration on the current (A) over the 24-hour treatment period. The dye is almost completely removed at the first pass of the contaminated water of the tank which, at the flow rate of 32 ml/min, takes about 3 hours to be completely purified. In fact, after about 3 hours the concentration of the dye is reduced to a value of 1.5 μg/l and maintains this value also in the tapping tested by means of UV-VIS analysis at 24 h.

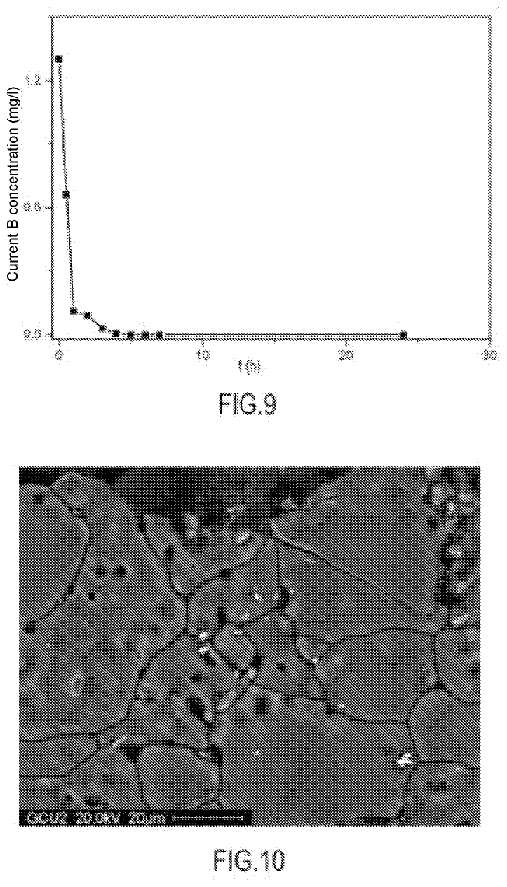

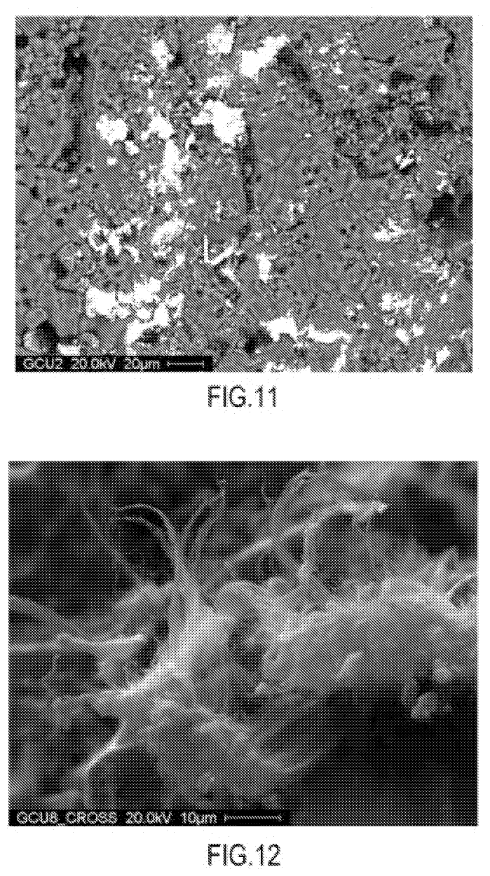

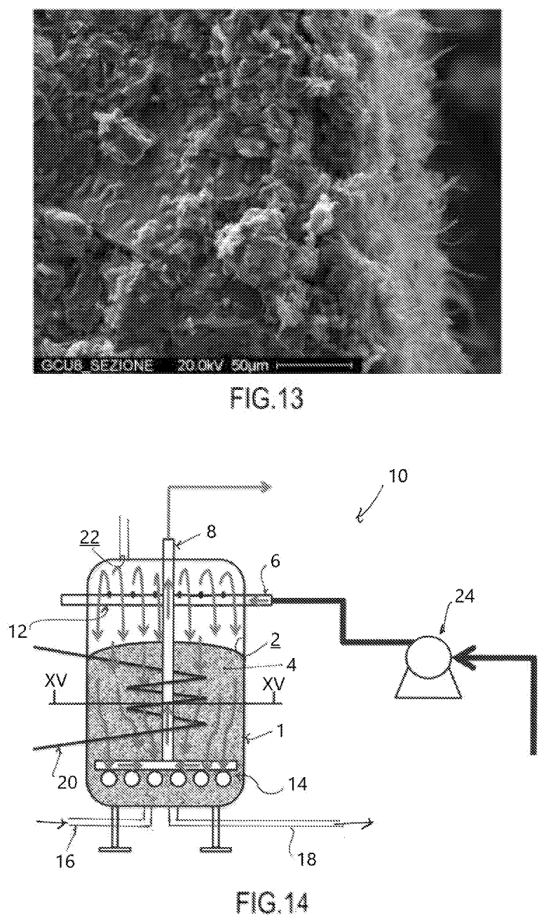

FIG. 9 shows the assessment of the concentration as a function of the treatment time in current B.

It is important to note that the concentration of current B after 30 mins dropped to slightly more than 1 mg/l and then dropped suddenly to 0.03 mg/l before stabilising at 1.5 g/l after 5 h of treatment, which is identical to that of current A.

Innovatively, the present invention allows to achieve the pre-set objectives.

More precisely, the present invention allows the CNTs to be anchored to a solid support upon the formation of carbon nanotubes, so that such blocking to the support does not require additional and further operations with respect to the synthesis by means of catalytic CVD.

According to an advantageous aspect, the CNTs according to the present invention are no longer free nanometric units, which would be substantially impossible to recover during use, but they are aggregated to an inert solid support which makes them easier to use.

Advantageously, the inert solid support subject of the present invention is extremely flexible, and it is capable of purifying aqueous solutions or biphasic systems with extremely fast and highly performing kinetics.

Advantageously, the separation method can be used for the removal of any organic substance, by virtue of the adsorbent power of the CNTs.

By way of example, the following are listed: Industrial dyes (for example: textile dyes), petroleum, petroleum fractions and petroleum derivatives, polyphenols (for example, oil industry discharges, oil mills and other food and food-related industries).

With respect to the embodiments of the aforementioned methods, of the inert solid material and of the adsorption system, a man skilled in the art may replace or modify the described characteristics according to the contingencies. These variants are also to be considered included in the scope of protection as outlined in the claims that follow.

Furthermore, it should be observed that any embodiment may be implemented independently from the other embodiments described.

### LIST OF REFERENCE NUMBERS

1 casing
2 inner compartment
4 adsorption bed
6 first supply duct
8 first outlet duct
10 adsorption system
12 dispensing means
14 collecting means
16 second supply duct
18 second outlet duct
20 heating means
22 venting opening
24 supply pump
26 radial collectors
28 regeneration solvent tank
30 basin or vat
32 a regeneration solvent evaporation unit
34 discharge duct
36 first intermediate duct
38 condensation unit
40 second intermediate duct
42 water tank
44 third intermediate ducts
46 fourth intermediate ducts
48 tubular furnace
50 manufacturing device
52 loading zone
54 heating zone
56 discharge zone
58 rotary reactor
60 carbon source supply pipe
62 drive means
64 rotating shaft
66 support surface
68 outer skirt
70 skirt compartment
72 inert gas inlet
74 annular volume
76 gas outlet
78 collector or discharge hopper
R rotation axis of the rotating reactor

1. Method for manufacturing inert solid supports with optionally functionalised carbon nanotubes (CNTs), comprising steps of:
i) providing inert solid supports and at least one catalytic metal absorbed in, or adsorbed or deposited on, said supports, said metal being optionally selected from among the group consisting of iron, cobalt, nickel, molybdenum and combinations thereof;
ii) supplying a gaseous, liquid or solid carbon source to the catalytic metal;
iii) through chemical vapor deposition (CVD), depositing at the catalytic metal at least part of the carbon source as CNTs, stably connected to the inert solid supports;
wherein the inert solid supports are in the form of particulate, granule or pellet with an over-nanometric particle size distribution, that is inert solid supports having an average size distribution comprised from 0.1 mm to 5 mm, and wherein the CNTs are in the form of scattered bundles or tangle, grouped at the catalytic metal.

2. The method according to claim 1, wherein the inert solid supports are selected from among the group consisting of aluminium silicate (for example: mullite), silico-aluminates, quartz sand, quartz, alumina or aluminium oxide (for example: corundum), silicon carbide, silicon nitride, zirconium oxide, calcium-magnesium carbonate (for example: dolomite), clay refractory materials, zeolite (for example natural or synthetic) and combinations thereof.

3. The method according to claim 1, wherein the inert solid supports are quartz sand.

4. The method according to claim 2, wherein the inert solid supports have an average size distribution comprised from 0.2 mm to 2 mm, preferably comprised from 0.3 mm to 1 mm.

5. Inert solid supports comprising optionally functionalised CNTs deposited on and stably connected to said support, said support comprising at least one catalytic metal absorbed in, or adsorbed or deposited on, said supports, wherein the inert solid supports are in the form of particulate, granule or pellet with an over-nanometric distribution of particle size, that is inert solid supports having an average size distribution comprised from 0.1 mm to 5 mm, and wherein the CNTs are in the form of scattered bundles or tangle, grouped at the catalytic metal.

6. A system (10) for the adsorption of at least one organic substance, for example of at least one organic pollutant, comprising the inert solid supports according to claim 5, the carbon nanotubes being configured to adsorb said organic substance, wherein said adsorption system (10) comprises:
a casing (1) defining an inner compartment (2) in which an adsorption bed (4) formed by a plurality of said inert solid supports comprising CNTs is arranged;
a first supply duct (6) for supplying a liquid to be purified to the adsorption bed (4), said liquid to be purified comprising said at least one organic substance;
a first outlet duct (8) for conveying an at least partly purified liquid from said at least one organic substance outside the inner compartment (2).

7. The system according to claim 6, comprising:
dispensing means (12) of the liquid to be purified on the adsorption bed (4), positioned at one end of the first supply duct (6); and
collecting means (14) of the at least partly purified liquid, arranged inside or below the adsorption bed (4) and fluidically connected to the first outlet duct (8).

8. The system according to claim 6 or 7, comprising:
a second duct (16) for supplying a polar and aprotic regeneration solvent, for example acetone or dimethyl sulfoxide (DMSO), to the adsorption bed (4);
a second outlet duct (18) for conveying said regeneration solvent comprising said at least one organic substance—desorbed from the CNTs of said inert solid supports—outside the inner compartment (2);
heating means (20) in a thermal contact with, preferably housed within, the adsorption bed (4) to evaporate residues of the regeneration solvent from said bed (4);
a venting opening (22) of the evaporated regeneration solvent, passing through said casing (1).

9. The system according to claim 6, wherein said adsorption bed (4) has a vacuum factor, defined as a percentage ratio—for a given total volume occupied by inert solid supports comprising CNTs—between a vacant internal volume between said inert solid supports (interstitial or interparticle volume) and said occupied total volume, independent from the amount of organic substances adsorbed on said CNTs, said vacuum factor being comprised from 35% to 60%, preferably comprised from 40% to 55%, even more preferably comprised from 40.5% to 48%, for packings of said inert solid supports with an average size distribution comprised from 0.2 mm to 2 mm.

10. A separation method comprising steps of:
a) providing inert solid supports according to claim 5;
b) contacting the inert solid supports with a liquid containing at least one organic substance to be separated, for example containing at least one organic pollutant;
c) adsorbing the organic substance on the carbon nanotubes of said inert solid supports, so as to separate it from said liquid;
d) desorbing the organic substance of step c) from the carbon nanotubes through at least one sub-step of washing the carbon nanotubes using a polar and aprotic solvent, for example acetone or dimethyl sulfoxide (DMSO);
e) re-using at least part of the inert solid supports of step d) in step a).

11. The method according to claim 10, wherein step d) comprises a sub-step of evaporating said solvent at low pressure so as to leave a dry residue of desorbed organic substance.

12. A device (50) for manufacturing an inert solid supports with carbon nanotubes (CNTs) comprises a tubular furnace (48) and a reactor (58) rotating with respect to said furnace (48) around a rotation axis (R); wherein said manufacturing device (50) comprises a loading zone (52), a heating zone (54) at said tubular furnace (48), and a discharge zone (56);
said rotary reactor (58) being rotatably mounted with respect to said furnace (48) so that a plurality of segments of said reactor (58) are movable in circular motion from the loading zone (52), to the heating zone (54), to the discharge zone (56).

13. The manufacturing device according to claim 12, wherein the heating zone (54) corresponds to a reaction zone, wherein said reaction zone is an annular volume (74) extending around the rotation axis (R) and which is radially delimited towards the outside by the loading zone (52) and/or the discharge zone (56).

14. The manufacturing device according to claim 12, wherein the rotary reactor (58) delimits a support surface (66) which is non-orthogonal with respect to the rotation axis (R), for example tilted at an angle comprised from 2° to 20°, preferably comprised from 5° to 15°, even more preferably comprised from 8° to 12°, with respect to a plane orthogonal to said axis (R), so as to promote a movement of the inert solid supports from the loading zone (52), to the heating zone (54), to the discharge zone (56).
